(19) United States
(12) Patent Application Publication
(10) Pub. No.: US 2009/0111240 A1
(43) Pub. Date: Apr. 30, 2009

(54) METHOD OF MANUFACTURING SEMICONDUCTOR DEVICE

(75) Inventor: Yukihiro HASHIMOTO, Kawasaki (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignee: FUJITSU MICROELECTRONICS LIMITED, Tokyo (JP)

(21) Appl. No.: 12/251,856

(22) Filed: Oct. 15, 2008

(30) Foreign Application Priority Data
Oct. 29, 2007 (JP) 2007-280892

(51) Int. Cl. H01L 21/762

(52) U.S. Cl. 438/427; 257/E21.546

(57) ABSTRACT

According to an aspect of an embodiment, a method of manufacturing a semiconductor device has forming a mask including a first silicon nitride film over a semiconductor substrate, forming a trench in a surface of the semiconductor substrate using the mask, forming a silicon oxide film over the mask to embed the silicon oxide film in the trench, performing a first nitriding treatment to selectively convert a portion of the silicon oxide film above the trench into an oxynitride film, performing a second nitriding treatment of the silicon oxide and oxynitride film to form a second silicon nitride film, and planarizing the first silicon nitride film and second silicon nitride film.

### CROSS-REFERENCE TO RELATED APPLICATION

This application is based upon and claims the benefit of priority of the prior Japanese Patent Application No. 2007-280892 filed on Oct. 29, 2007, the entire contents of which are incorporated herein by reference.

### BACKGROUND

1. Field

The embodiments discussed herein are directed to a method of manufacturing a semiconductor device.

2. Description of Related Art

Shallow trench isolation (STI) has been used in processes for forming element isolation films. FIG. 3 is a cross-sectional view showing a known process for forming element isolation films using the STI technique. A process for forming element isolation films in a method of manufacturing a semiconductor device provided with a memory portion 102 and a logic circuit portion 101 will be described below.

In the known process, a hard mask composed of a silicon oxide film 111 and a silicon nitride film 112 is formed on a semiconductor substrate 151, and using the hard mask, trenches 113 and 114 are formed. Next, a silicon oxide film 115 is formed by high-density plasma chemical vapor deposition (CVD) so as to be embedded in the trenches 113 and 114. Then, the silicon oxide film 115 is planarized by chemical mechanical polishing (CMP). In the planarization process, the silicon nitride film 112 contained in the hard mask is also polished.

As shown in FIG. 3, in the known process, it is desirable to allow the silicon oxide film 115 to remain with an appropriate thickness in the trench 113 in the logic circuit portion 101. This is mainly due to the following two reasons.

Firstly, the polishing rate of the silicon oxide film 115 formed by high-density plasma CVD is significantly higher than the polishing rate of the silicon nitride film 112. Secondly, depending on the type of integrated circuit, the sizes of the individual element isolation regions required therein significantly differ. For example, in the logic circuit portion 101, a large element isolation region is required compared with the memory portion 102. Consequently, the variation in the size of the trench is large, and the variation in the thickness of the silicon oxide film 115 is also large. Because of the difference in the polishing rate and the variation in the thickness of the silicon oxide film 115 as described above, in the logic circuit portion 101, which requires a larger element isolation region than the memory portion 102, as shown in FIG. 3, the silicon oxide film 115 in the trench 113 is excessively polished.

Furthermore, if the amount of polishing by CMP is decreased, as shown in FIG. 4A, the thickness of the silicon oxide film 115 in the trench 113 may be set to be an appropriate level. However, the silicon oxide film 115 excessively remains in the trenches 114. After the polishing process by CMP, the silicon nitride film 112 is removed by a wet treatment using phosphoric acid. This removal results in a large difference in level due to the remaining silicon oxide film 115 in the memory portion 102 as shown in FIG. 4B. Such a large difference in level may cause residues to remain in the subsequent process of forming interconnect lines. Because of the residues, short-circuiting or junction leakage may occur. Consequently, the control of the amount of polishing by CMP is not considered to be appropriate means.

Furthermore, Patent Documents 1 to 4 describe techniques in which a polishing stopper is selectively formed. It is desirable to obtain appropriate element isolation regions even by using these techniques.

[Patent Document 1] Japanese Laid-open Patent Publication No. 09-51034

[Patent Document 2] Japanese Laid-open Patent Publication No. 10-22374

[Patent Document 3] Japanese Laid-open Patent Publication No. 2000-36533

[Patent Document 4] Japanese Laid-open Patent Publication No. 2000-357731

### SUMMARY

According to an aspect of an embodiment, a method of manufacturing a semiconductor device has forming a mask including a first silicon nitride film over a semiconductor substrate, forming a trench in a surface of the semiconductor substrate using the mask, forming a silicon oxide film over the mask to embed the silicon oxide film in the trench, performing a first nitriding treatment to selectively convert a portion of the silicon oxide film above the trench into an oxynitride film, performing a second nitriding treatment of the silicon oxide and oxynitride film to form a second silicon nitride film; and planarizing the first silicon nitride film and second silicon nitride film.

### BRIEF DESCRIPTION OF THE DRAWINGS

FIGS. 1A to 1I are cross-sectional views showing processes of forming element isolation films in sequence in a method of manufacturing a semiconductor device according to an embodiment of the present technique;

FIGS. 2A to 2D are cross-sectional views showing processes in sequence in a method of manufacturing a semiconductor device according to an embodiment of the present technique;

FIG. 3 is a cross-sectional view showing a known process for forming element isolation films using an STI technique; and

FIGS. 4A and 4B are cross-sectional views showing processes in sequence in another process for forming element isolation films using the STI technique.

### DESCRIPTION OF THE PREFERRED EMBODIMENTS

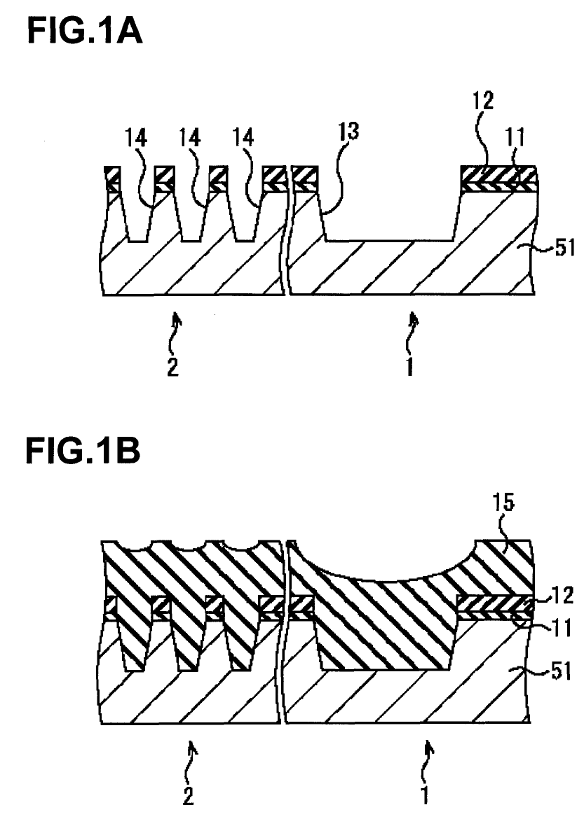

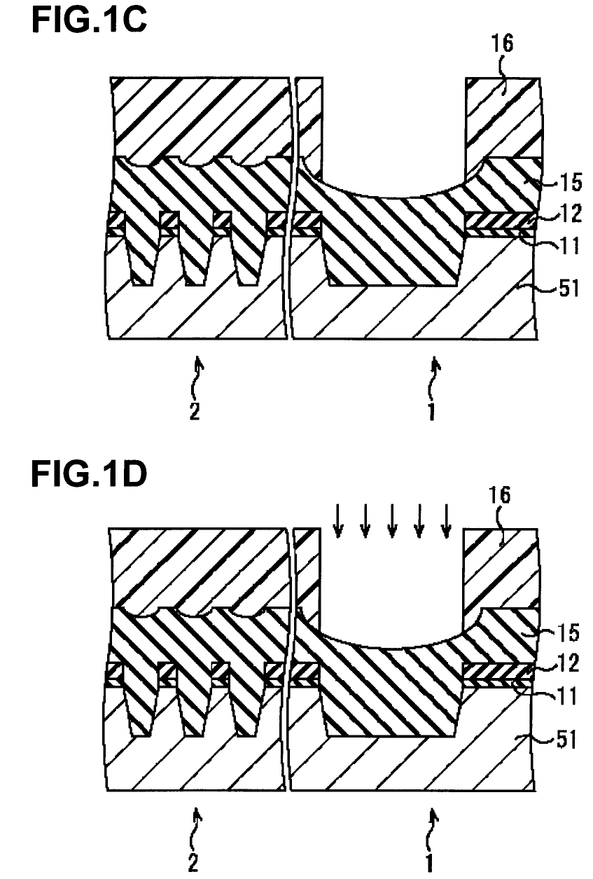

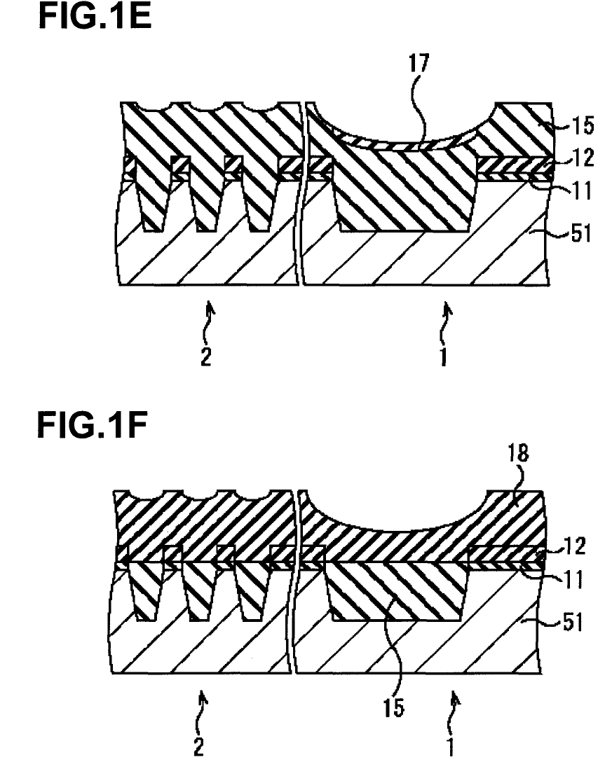

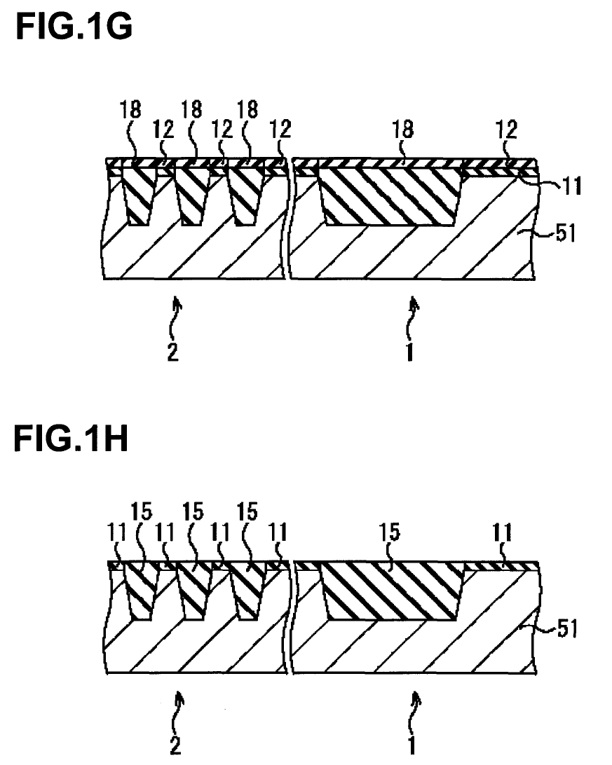

An embodiment of the present technique will be described in detail with reference to the drawings. FIGS. 1A to 1I are cross-sectional views showing processes of forming element isolation films in sequence in a method of manufacturing a semiconductor device according to the embodiment. A process for forming element isolation films using an STI technique in a method of manufacturing a flash memory provided with a memory portion 2 and a logic circuit portion 1 will be described below. The memory portion 2 includes memory cells of the flash memory. The logic circuit portion 1 includes a logic circuit used for driving the memory cells.

First, as shown in FIG. 1A, for example, a silicon oxide film 11 with a thickness of 10 nm and a silicon nitride film (first silicon nitride film) 12 with a thickness of 100 nm are formed on a semiconductor substrate 51, and then patterning is performed. The silicon oxide film 11 is formed, for example, by thermal oxidation. The silicon nitride film 12 is formed, for example, by CVD. Next, using the silicon oxide film 11 and the silicon nitride film 12 as a hard mask, the semiconductor substrate 51 is subjected to etching. Thereby, a trench 13 for element isolation is formed in the logic circuit portion 1, and trenches 14 for element isolation are formed in the memory portion 2. The width of the trench 13 is about 10.0 μm at a maximum.

Then, a thin sacrificial oxide film (not shown) is formed on the surfaces of the trenches 13 and 14, and as shown in FIG. 1B, a silicon oxide film 15 is formed by high-density plasma CVD so as to be embedded in the trench 13 and the trenches 14. The thickness of the silicon oxide film 15 is, for example, 300 nm with respect to the surface of the silicon nitride film 12. Furthermore, irregularities occur in the surface of the silicon oxide film 15 due to the trench 13 and the trenches 14.

Subsequently, as shown in FIG. 1C, a resist pattern 16 is formed on the silicon oxide film 15, the resist pattern 16 having an opening located above the trench 13.

Subsequently, as shown in FIG. 1D, using the resist pattern 16 as a mask, nitrogen ions are implanted in the surface of the silicon oxide film 15 at a dose of about 5.0×10¹⁵ cm⁻² to 2.0×10¹¹ cm⁻².

Then, as shown in FIG. 1E, the resist pattern 16 is removed. Subsequently, annealing (first nitriding treatment) is performed, for example, in a nitrogen atmosphere at about 900° C. to 1,000° C. Thereby, a silicon oxynitride film 17 with a thickness of about 20 to 100 nm is formed at the portion of the silicon oxide film 15 implanted with nitrogen ions.

Subsequently, by performing annealing (second nitriding treatment) in an ammonia atmosphere at about 700° C. to 900° C. using a diffusion furnace or the like, as shown in FIG. 1F, a portion of the silicon oxide film 15 located at a level higher than the surface of the silicon oxide film 11 is converted into a silicon nitride film 18 (second silicon nitride film). In this process, since the silicon oxynitride film 17 has been formed above the trench 13, the portion of the silicon oxide film 15 located above the trench 13 is not easily nitrided compared with the portions of the silicon oxide film 15 located above the trenches 14. For example, the nitriding rate of the silicon oxide film 15 at the portion located above the trench 13 is about one third of the nitriding rate of the silicon oxide film 15 at the portion located above the trenches 14. Consequently, the time required for nitriding the portion of the silicon oxide film 15 located above the trench 13 is substantially the same as that for the portion of the silicon oxide film 15 located above the trenches 14. Thereby, only the silicon nitride film 12 and the silicon nitride film 18 are present on and above the silicon oxide film 11.

Next, as shown in FIG. 1G, the silicon nitride films 18 and 12 are subjected to polishing (planarization) by CMP. In the polishing process, the silicon nitride films 18 and 12 are not completely removed, but the polishing is terminated in the middle of the silicon nitride films 12 and 18. For example, each of the silicon nitride film 12 and the silicon nitride film 18 is allowed to remain with a thickness of about 20 nm.

Subsequently, as shown in FIG. 1H, the silicon nitride films 12 and 18 are removed by a wet treatment (wet etching) using phosphoric acid. Then, as shown in FIG. 1I, the silicon oxide film 11 is removed and a surface portion of the silicon oxide film 15 is removed by the same thickness as the silicon oxide film 11. Thereby, element isolation films are formed by the STI technique.

In this embodiment, the films subjected to polishing by CMP are silicon nitride films only. Therefore, even if irregularities are present on the surfaces of the silicon nitride films, the irregularities are gradually reduced, and finally the irregularities of the silicon nitride films disappear. Consequently, high flatness may be obtained. That is, in each of the logic circuit portion 1 and the memory portion 2, the surface of the element isolation film may be planarized, and the difference in level between element isolation films and element active regions may be reduced.

In the method described above, nitridation is performed on the portion of the silicon oxide film 15 at a level higher than the surface of the silicon oxide film 11. However, since the silicon oxide film 11 is very thin, the nitridation may be performed on a portion of the silicon oxide film 15 at a level higher than the surface of the semiconductor substrate 51. That is, as long as the portions inside of the trenches 13 and 14 are not nitrided, strict control is not necessary.

Furthermore, the dose of nitrogen ions and various conditions, such as the temperature and time, for annealing in an ammonia atmosphere are not particularly limited, and the appropriate ranges may be easily determined depending on the size of the element isolation films, the density, etc.

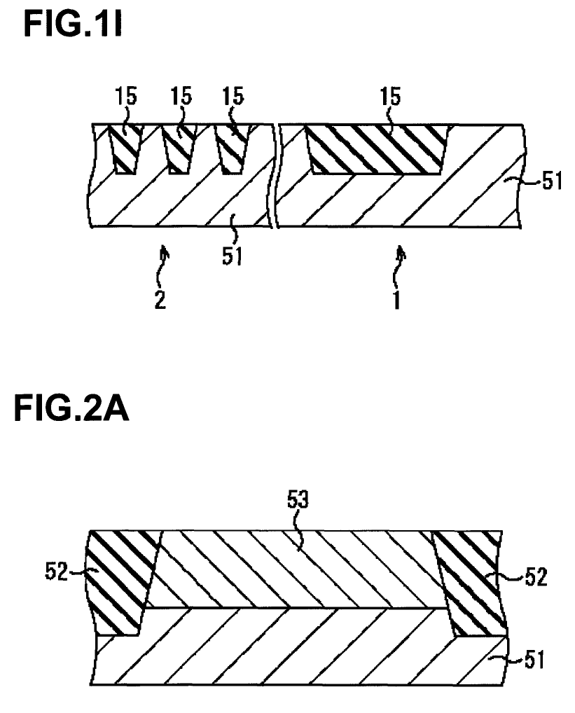

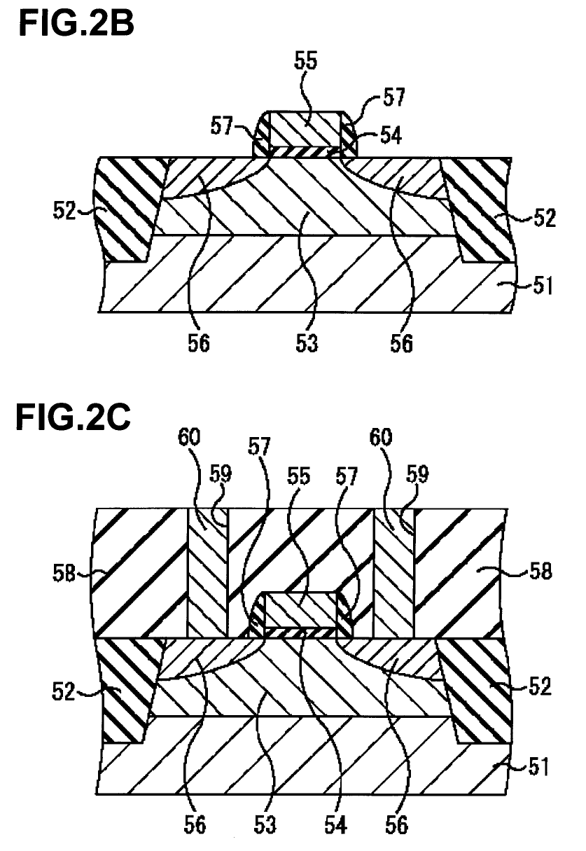

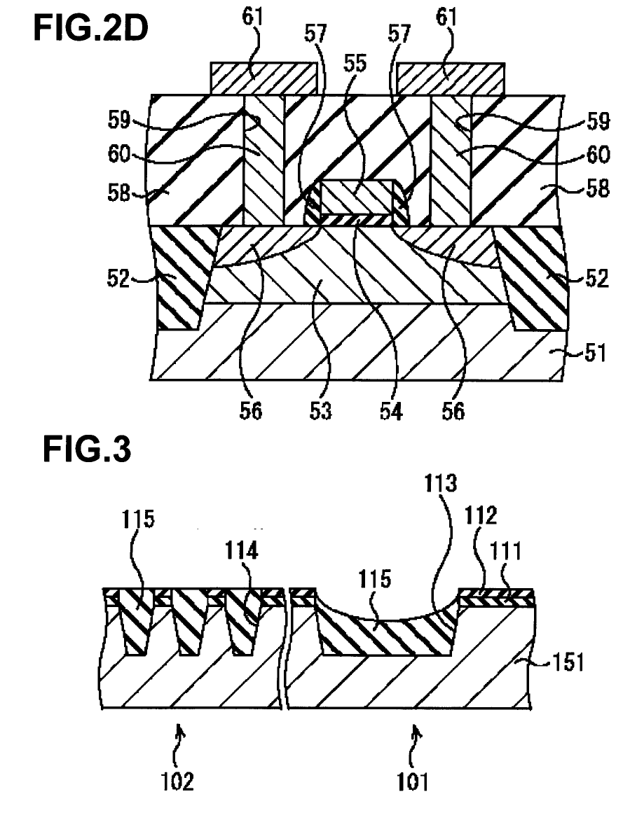

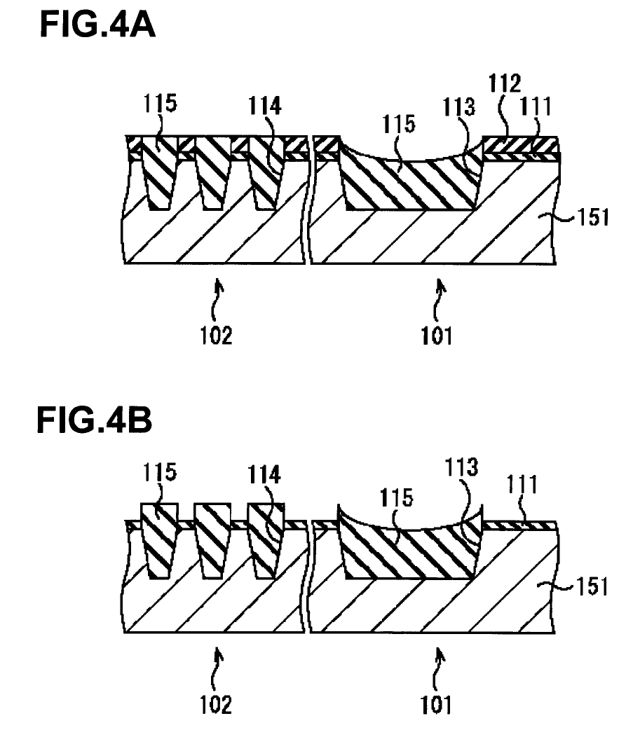

A process after the element isolation films are formed will now be described. FIGS. 2A to 2D are cross-sectional views showing processes in sequence in a method of manufacturing a semiconductor device according to an embodiment.

First, as shown in FIG. 2A, a well 53 is formed in an element active region of the semiconductor substrate 51 provided with element isolation films 52 including the silicon oxide film 15.

After the well 53 is formed, as shown in FIG. 2B, a gate insulating film 54 and a gate electrode 55 are formed. After the gate insulating film 54 and the gate electrode 55 are formed, impurity diffusion layers 56 and sidewall insulating films 57 are formed. Thereby, a field-effect transistor is formed.

After the field-effect transistor is formed, as shown in FIG. 2C, an interlayer insulating film 58 is formed so as to cover the field-effect transistor, and contact holes 59 are formed therein, the contact holes 59 extending to the impurity diffusion layers 56. After the contact holes 59 are formed, contact plugs 60 are formed in the contact holes 59.

After the contact plugs 60 are formed, as shown in FIG. 2D, interconnect lines 61 that are to be connected to the contact plugs 60 are formed on the interlayer insulating film 58.

Subsequently, upper interconnect lines, interlayer insulating films, etc. are formed to complete a semiconductor device. Furthermore, a semiconductor element other than the field-effect transistor may be formed in the element active region.

According to the method described above, since a semiconductor element, such as a field-effect transistor, is formed in the element active region in which the difference in level from the element isolation films is reduced, problems, such as occurrence of the residues resulting from the unnecessary difference in level may be prevented.

What is claimed is:

1. A method of manufacturing a semiconductor device, comprising:
forming a mask including a first silicon nitride film over a semiconductor substrate;
forming a trench in a surface of the semiconductor substrate using the mask;
forming a silicon oxide film over the mask to embed the silicon oxide film in the trench;
performing a first nitriding treatment to selectively convert a portion of the silicon oxide film above the trench into an oxynitride film;
performing a second nitriding treatment of the silicon oxide and oxynitride film to form a second silicon nitride film; and
planarizing the first silicon nitride film and second silicon nitride film.

2. The method according to claim 1, wherein the performing the second nitriding treatment forms the second silicon nitride film over the surface of the semiconductor substrate.

3. The method according to claim 1, wherein the performing the first nitriding treatment includes implanting nitrogen ions in the surface of the silicon nitride film and performing a heat treatment of the portion where the nitrogen ions are implanted.

4. The method according to claim 3, wherein the performing the heat treatment is performed in the atmosphere including nitrogen.

5. The method according to claim 3, wherein the performing the first nitriding treatment includes forming the resist pattern used as a mask over the silicon oxide film before the implanting nitrogen ions in the surface of the silicon nitride film.

6. The method according to claim 1, wherein the performing the second nitriding treatment is performed by annealing in an ammonia atmosphere.

7. The method according to claim 1, wherein first and second trenches are formed by the forming the trench in the surface of the semiconductor substrate using the mask, and the silicon oxynitride film is selectively formed over the first trench having a width which is greater than that of the second trench.

8. The method according to claim 7, wherein the second trench is formed in a memory region including a memory cell and the first trench is formed in a logic circuit region including a logic circuit.

9. The method according to claim 1, wherein the planarizing the first silicon nitride film and second silicon nitride film are performed by a chemical mechanical polishing method.

10. The method according to claim 1, wherein the silicon oxide film is formed by a high-density plasma chemical vapor deposition.

11. The method according to claim 1, further comprising removing the remained first and second nitride films by a wet treatment using phosphonic acid after the planarizing the first silicon nitride film and second silicon nitride film.
